(19) United States
(12) Patent Application Publication
(10) Pub. No.: US 2005/0102720 A1
(43) Pub. Date: May 12, 2005

(54) Magnetic tunnel junction device with etch stop layer and dual-damascene conductor

(76) Inventor: Heon Lee, Pohang-Si (KR)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/692,774

(22) Filed: Oct. 24, 2003

(51) Int. Cl. H01L 21/00

(52) U.S. Cl. 977/DIG. 1

(57) ABSTRACT

A method of making a magnetic tunnel junction device is disclosed. The method includes forming an etch stop layer on a magnetic tunnel junction stack. In subsequent etching steps, the etch stop layer protects one or more layers of magnetic material in the magnetic tunnel junction stack from chemical erosion caused by an etch material, such as an etch material that includes the chemical fluorine (F), for example. The etch stop layer is made from an electrically conductive material. The method also reduces the number of process steps by forming a self-aligned via in a dielectric layer. A deposition of a second electrically conductive material completely fills the self-aligned via and covers the dielectric layer to form a dual-damascene conductor in one processing step. The dual-damascene conductor includes a via positioned in the self-aligned via and a top conductor in contact with the dielectric layer.

### FIELD OF THE INVENTION

The present invention relates generally to a method of making a magnetic tunnel junction device. More specifically, the present invention relates to a method of making a magnetic tunnel junction device with a self-aligned via and a dual damascene conductor that is in contact with an etch stop layer that prevents chemical erosion of one or more layers of a magnetic material of the magnetic tunnel junction device during an etching process.

### BACKGROUND OF THE INVENTION

An magnetoresistance random access memory (MRAM) includes an array of memory cells. Each memory cell is a magnetic tunnel junction device. The magnetic tunnel junction device operates on the principles of spin tunneling. There are several types of magnetic tunnel junction devices including two prominent types, tunneling magnetoresistance (TMR) and giant magnetoresistance (GMR). Both types of devices comprise several layers of thin film materials and include a first layer of magnetic material in which a magnetization is alterable and a second layer of magnetic material in which a magnetization is fixed or “pinned” in a predetermined direction. The first layer is commonly referred to as a data layer or a sense layer; whereas, the second layer is commonly referred to as a reference layer or a pinned layer. The data layer and the reference layer are separated by a very thin tunnel barrier layer. In a TMR device, the tunnel barrier layer is a thin film of a dielectric material (e.g. silicon oxide SiO₂). In contrast, in a GMR device, the tunnel barrier layer is a thin film of an electrically conductive material (e.g. copper Cu).

Electrically conductive traces, commonly referred to as word lines and bit lines, or collectively as write lines, are routed across the array of memory cells with a memory cell positioned at an intersection of a word line and a bit line. The word lines can extend along rows of the array and the bit lines can extend along columns of the array, or vice-versa. A single word line and a single bit line are selected and operate in combination to switch the alterable orientation of magnetization in the memory cell located at the intersection of the selected word and bit lines. A current flows through the selected word and bit lines and generates magnetic fields that collectively act on the alterable orientation of magnetization to cause it to switch (i.e. flip) from a current state (i.e. a logic zero “0”) to a new state (i.e. a logic “1”). Typically, the alterable orientation of magnetization is aligned with an easy axis of the data layer and the magnetic field causes the alterable orientation of magnetization to flip from an orientation that is parallel with the pinned orientation of the reference layer or to an orientation that is anti-parallel to the pinned orientation of the reference layer. The parallel and anti-parallel orientations can represent the logic states of “0” and “1” respectively, or vice-versa.

Because the layers of material that comprise the magnetic tunnel junction device are very thin layers of material (e.g. on the order of about 15.0 nm or less), the manufacturing of defect free magnetic tunnel junction devices can be quite difficult. Those defects can include variations in magnetic switching characteristics among memory cells in the same array, defects in the tunnel barrier layer, and defects in the layer(s) of magnetic materials that comprise the data layer and/or the reference layer. Additionally, magnetic materials are also used for anti-ferromagnetic layers, cap layers, seed layers, and pinning layers, etc.

In FIGS. 1a and 1b, a prior magnetic tunnel junction device 200 can include a bottom conductor 213 that can be a bit line, a seed layer 211 (e.g. made from tantalum Ta), a pinned layer 209 of a magnetic material (e.g. made from nickel iron NiFe) and including a pinned orientation of magnetization m₁, a tunnel barrier layer 207 (e.g made from aluminum oxide Al₂O₃ for a TMR device), a data layer 205 of a magnetic material (e.g. made from nickel iron cobalt NiFeCo) and including an alterable orientation of magnetization m₂, a cap layer 203 (e.g. made from tantalum Ta), and a top conductor 201 that can be a word line.

One disadvantage to prior methods for manufacturing the magnetic tunnel junction device 200 is that many processing steps are required. As a result, yield can be compromised by any of those steps. For example, the process for forming the top conductor 201 can require several processing steps that can include: in a first step, forming a via in a dielectric layer (not shown) that extends to the data layer 205; filling the via with an electrically conductive material; and then in a second step, depositing another electrically conductive material to form the top conductor 201. Generally, more processing steps increases the risk that one of those steps will introduce a defect that will render the magnetic tunnel junction device 200 inoperable, with a resulting decrease in yield.

Another disadvantage to prior methods for manufacturing the magnetic tunnel junction device 200 is that the chemicals used during some of the processing steps can chemically attack or erode the magnetic materials that are used to form some of the thin film layers of the magnetic tunnel junction device 200. For example, the above mentioned via can be formed by using a plasma or wet etch process P to remove a layer of dielectric material that covers the cap layer 203. Because the layers of material are very thin, during an over etch step, etch materials that are fluoride (F) based can permeate the cap layer 203 and the layers below it to chemically erode E the magnetic materials in the data layer 205, the reference layer 209, and any other layers that include magnetic materials such as nickel (Ni), iron (Fe), and cobalt (Co), for example.

Consequently, there is a need for a method of making a magnetic tunnel junction device that reduces the number of processing steps. There is also a need for a method of making a magnetic tunnel junction device that protects the layers of magnetic material from erosion caused by chemicals used in the processing of the magnetic tunnel junction device.

### SUMMARY OF THE INVENTION

The present invention is embodied in a method of making a magnetic tunnel junction device. The magnetic tunnel junction device solves the aforementioned problems associated with chemical erosion of the plurality of layers of the magnetic material that are part of the magnetic tunnel junction stack by forming an etch stop layer made from a first electrically conductive material on the magnetic tunnel junction stack. The plurality of layers of magnetic material are positioned below the etch stop layer. The etch stop layer serves as a barrier that protects the underlying layers of magnetic material during subsequent etching steps. Chemicals contained in the etchant material, such as fluorine (F), that can chemically erode the magnetic materials, are prevented from attacking the magnetic materials by the barrier imposed by the etch stop layer.

Moreover, the aforementioned problems caused by additional process steps and their potential for creating defects in the magnetic tunnel junction device are solved by a dual-damascene conductor that includes a via and a top conductor that are homogeneously formed in a single process step. Consequently, fewer process steps are required to manufacture the magnetic tunnel junction device and yield can be increased because fewer process steps are required.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1a is a cross-sectional view depicting a prior magnetic tunnel junction device.

FIG. 1b is a cross-sectional view depicting erosion of layers of magnetic material in a prior magnetic tunnel junction device during an etching step.

FIG. 2 is a flow diagram depicting a method of making a magnetic tunnel junction device.

FIG. 3 is a cross-sectional view depicting a discrete magnetic tunnel junction stack including an etch stop layer.

FIG. 4 is a cross-sectional view depicting a magnetic tunnel junction device including a dual-damascene conductor and an etch stop layer.

FIG. 5 is a cross-sectional view depicting a magnetic tunnel junction stack.

FIG. 6a is a cross-sectional view depicting a patterning of a magnetic tunnel junction stack.

FIG. 6b is a cross-sectional view depicting an etching of a magnetic tunnel junction stack.

FIG. 7 is a cross-sectional view depicting a discrete magnetic tunnel junction stack including an etch stop layer and a plurality of thin film layers.

FIG. 8 is a cross-sectional view depicting a dielectric layer formed on the the discrete magnetic tunnel junction stack of FIG. 7.

FIG. 9 is a cross-sectional view depicting a planarized dielectric layer.

FIG. 10a and FIG. 10b are a cross-sectional views depicting an etching of a first mask layer.

FIG. 11 is a cross-sectional view depicting a second electrically conductive material formed on a dielectric layer and in a self-aligned via.

FIG. 12 is a cross-sectional view depicting a patterning and an etching of a second electrically conductive material.

FIG. 13 is a cross-sectional view depicting a magnetic tunnel junction device including a dual-damascene conductor and an etch stop layer.

FIG. 14 is a cross-sectional view depicting layers of magnetic materials that are protected from damage due to erosion by an etch stop layer.

FIG. 15 is a top plan view depicting an array of magnetic tunnel junction devices.

FIG. 16 is a cross-sectional view along line A-A of FIG. 15.

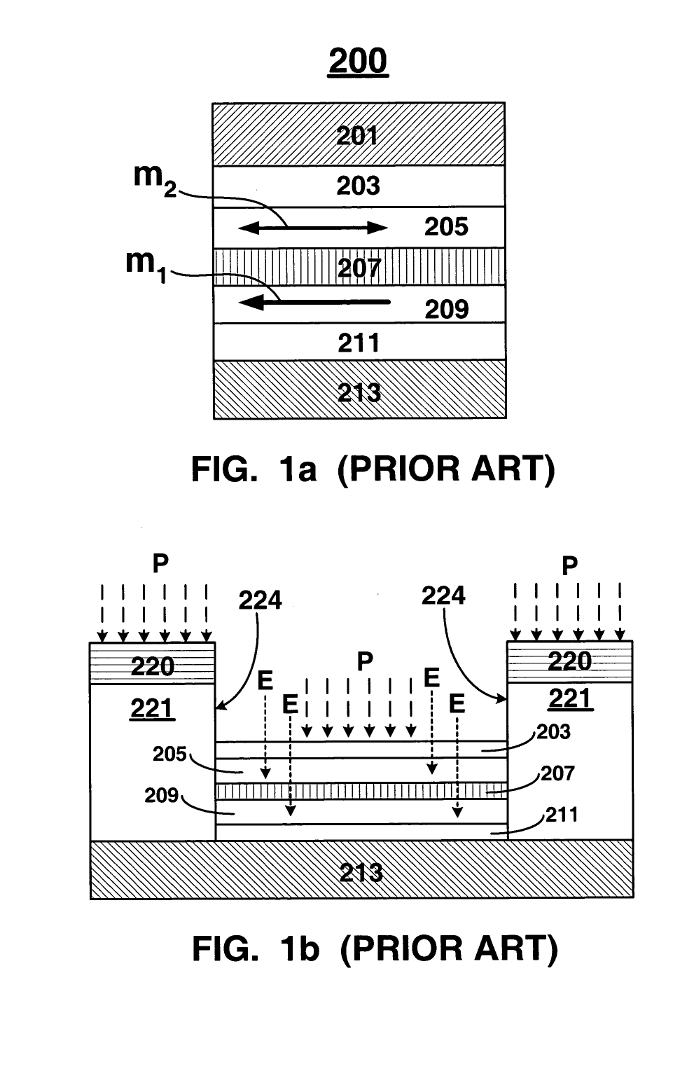

### DETAILED DESCRIPTION

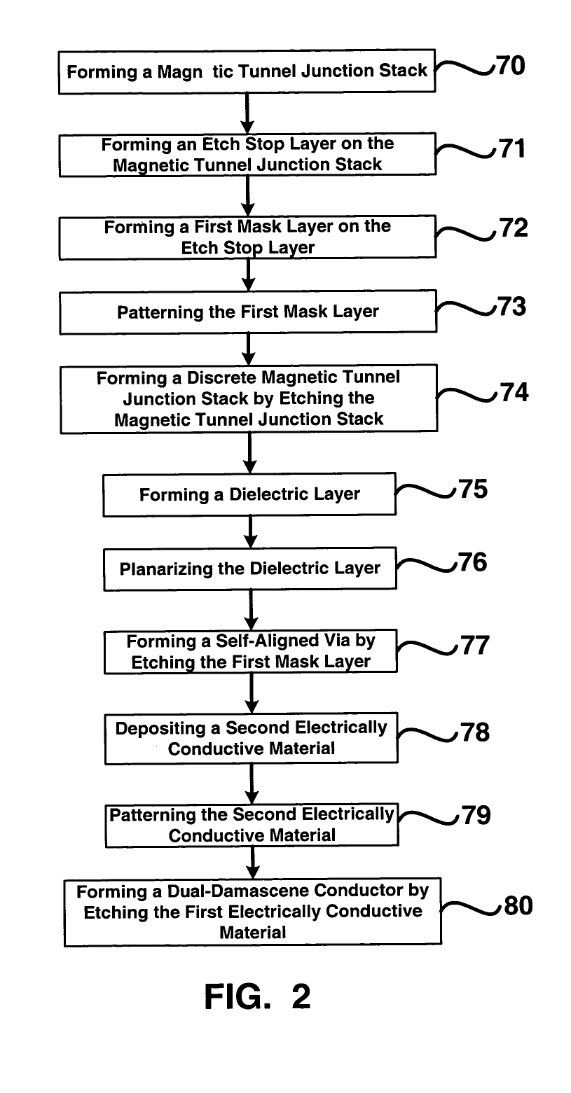

As shown in the drawings for purpose of illustration, the present invention is embodied in a method of making a magnetic tunnel junction device. In FIG. 2, the method includes forming 70 a magnetic tunnel junction stack, forming 71 an etch stop layer of a first electrically conductive material on the magnetic tunnel junction stack, forming 72 a first mask layer on the etch stop layer, and patterning 73 the first mask layer. A discrete magnetic tunnel junction stack is formed 74 by etching the magnetic tunnel junction stack, then a dielectric layer is formed 75 on the discrete magnetic tunnel junction stack followed by a planarizing 76 of the dielectric layer. A self-aligned via is formed 77 by etching the first mask layer. A second electrically conductive material is deposited 78 in the self-aligned via and on the dielectric layer. The second electrically conductive material is then patterned 79. A dual-damascene conductor is formed 80 by etching the second electrically conductive material.

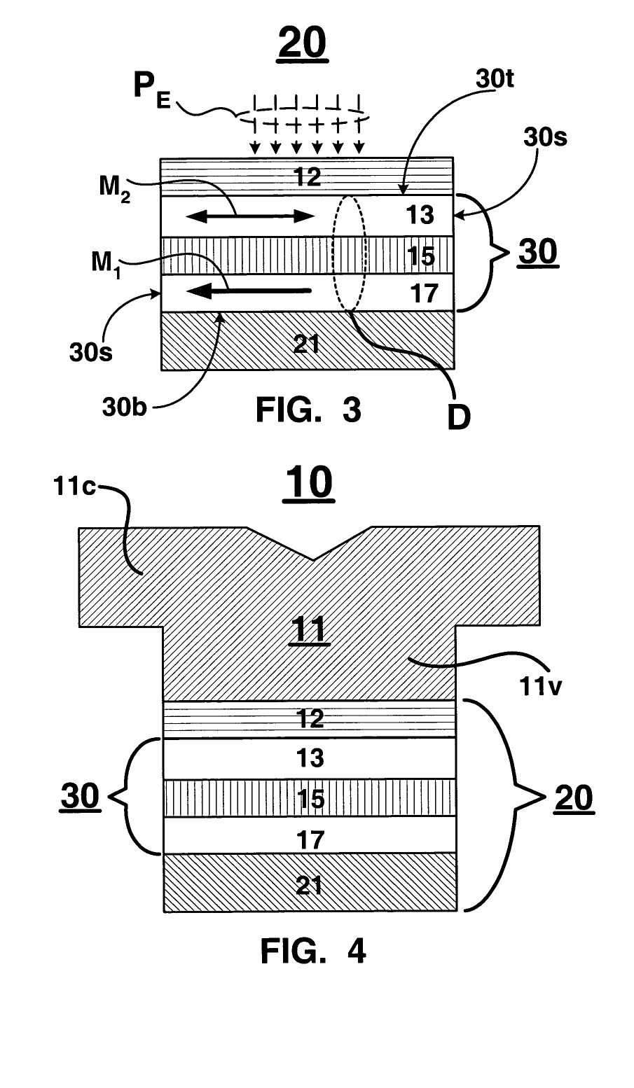

In FIG. 3, a discrete magnetic tunnel junction stack 20 can include a plurality of thin film layers of materials that are well know in the MRAM art. Those layers include but are not limited to a reference layer 17 (also called a pinned layer) made from a magnetic material and including a pinned orientation of magnetization M₁, a tunnel barrier layer 15 that can be a dielectric material for a TMR device or an electrically conductive material for a GMR device, and a data layer 13 (also called a sense layer) made from a magnetic material and including an alterable orientation of magnetization M₂. The discrete magnetic tunnel junction stack 20 also includes an etch stop layer 12 made from a first electrically conductive material as will be described below and an electrically conductive material 21 that can be a bottom conductor or electrode, for example. Unless otherwise noted, the thin film layers (13, 15, 17) of the magnetic tunnel junction stack 20 will be collectively denoted as the layers 30. The layers 30 include a top portion 30t, a bottom portion 30b, and side portions 30s. For purposes of illustration, other layers that can be included in the layers 30 are not depicted in FIG. 3. Those layers include but are not limited to cap layers, seed layers, pinning layers, anti-ferromagnet layers, and artificial anti-ferromagnetic layers, just to name a few.

Although the etch stop layer 12 is depicted in contact with the data layer 13, the method of the present invention includes forming the etch stop layer 12 on any suitable layer positioned at the top portion 30t of the thin film layers 30 so that during an etching process P_{E}, the underlying layers of magnetic material in the thin film layers 30 are not chemically eroded by chemicals in an etchant material used in the etching process P_{E}. Accordingly, the etch stop layer 12 serves as a barrier that prevents the chemical erosion of the plurality of layers of a magnetic material positioned below the etch stop layer 12 in the discrete magnetic tunnel junction stack 20. Consequently, after the etching process P_{E}, the thin film layers 30, particularly those layers that are made from a magnetic material, are not damaged D due to chemical erosion.

In FIG. 4, a magnetic tunnel junction device 10 fabricated according to the method depicted in FIG. 2, includes a dual-damascene conductor 11 that is formed on the discrete magnetic tunnel junction stack 20 and is in contact with the etch stop layer 12. The etch stop layer 12 is in contact with the top portion 30t of the thin film layers 30. The electrically conductive material 21 is in electrical communication with the bottom portion 30b of the thin film layers 30 and serves as a bottom conductor (also denoted as 21). The bottom conductor 21 can be in direct contact with the bottom portion 30b or can be in electrical communication with the bottom portion 30b through an intermediate structure such as a via or the like, for example. As will be described below, the dual-damascene conductor 11 includes a first portion 11v that fills a self-aligned via (not shown) and a second portion 11c that is in contact with a substantially planar surface of a dielectric material (not shown). The first and second portions (11v, 11c) are homogeneously formed with each other.

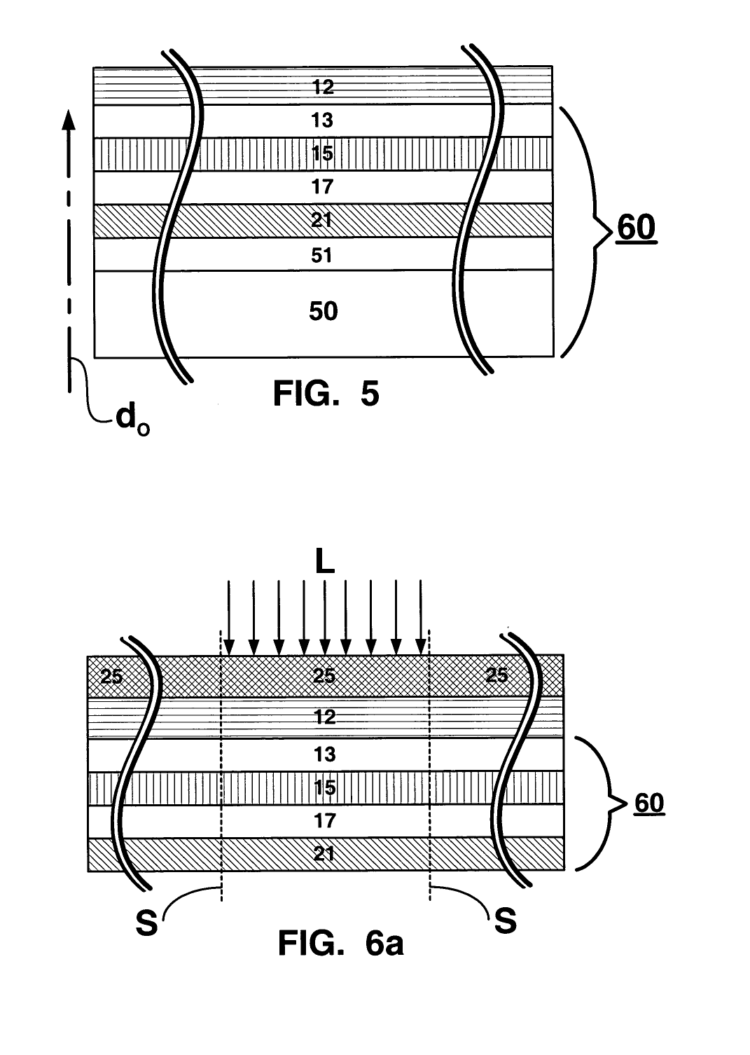

In FIG. 5 and referring to the above mentioned process as depicted in FIG. 2, at a stage 70, a magnetic tunnel junction stack 60 is formed by depositing a plurality of layers of thin film materials in a process order do. The processes and the materials used to form those layers of thin film materials are well understood in the microelectronics art. The magnetic tunnel junction stack 60 can include a substrate 50 that can be a semiconductor material, a silicon substrate, or a silicon wafer, for example. A dielectric layer 51 can be formed on the substrate 50. Suitable materials for the dielectric layer 51 include but are not limited to silicon oxide (SiO₂), for example. An electrically conductive material 21 can be formed on the dielectric layer 51 and can be a bottom conductor or an electrode that serves as a word line or bit line in an MRAM array. Suitable materials for the bottom conductor 21 include but are not limited to aluminum (Al) and tungsten (W), for example.

The other thin film layers in the magnetic tunnel junction stack 60 include but are not limited to: a reference layer 17 that can be made from nickel iron (NiFe) or alloys of those materials; a tunnel barrier layer 15 that can be made from aluminum oxide (Al₂O₃) or silicon oxide (SiO₂), and a data layer 13 that can be made from nickel iron cobalt (NiFeCo) or alloys of those materials. Examples of other layers that can be included in the magnetic tunnel junction stack 60 include a seed layer and a cap layer made from tantalum (Ta), a manganese iron (MnFe) AF pinning layer, just to name a few.

Deposition processes that are well known in the microelectronics art can be used to deposit the layers in the magnetic tunnel junction stack 60. For example, physical vapor deposition (PVD), plasma enhanced chemical vapor deposition (PECVD), and sputtering are deposition processes that can be used to form the aforementioned layers. PVD can include thermal evaporation and sputtering.

In FIG. 5, at a stage 71, an etch stop layer 12 is formed on the uppermost layer of the magnetic tunnel junction stack 60. Although FIG. 5 depicts the data layer 13 as the uppermost layer, the method is not limited to the arrangement of layers depicted herein. As an example, the uppermost layer of the magnetic tunnel junction stack 60 can be the reference layer 17 instead of the data layer 13. The etch stop layer 12 is made from a first electrically conductive material including but not limited to aluminum (Al) and alloys of aluminum.

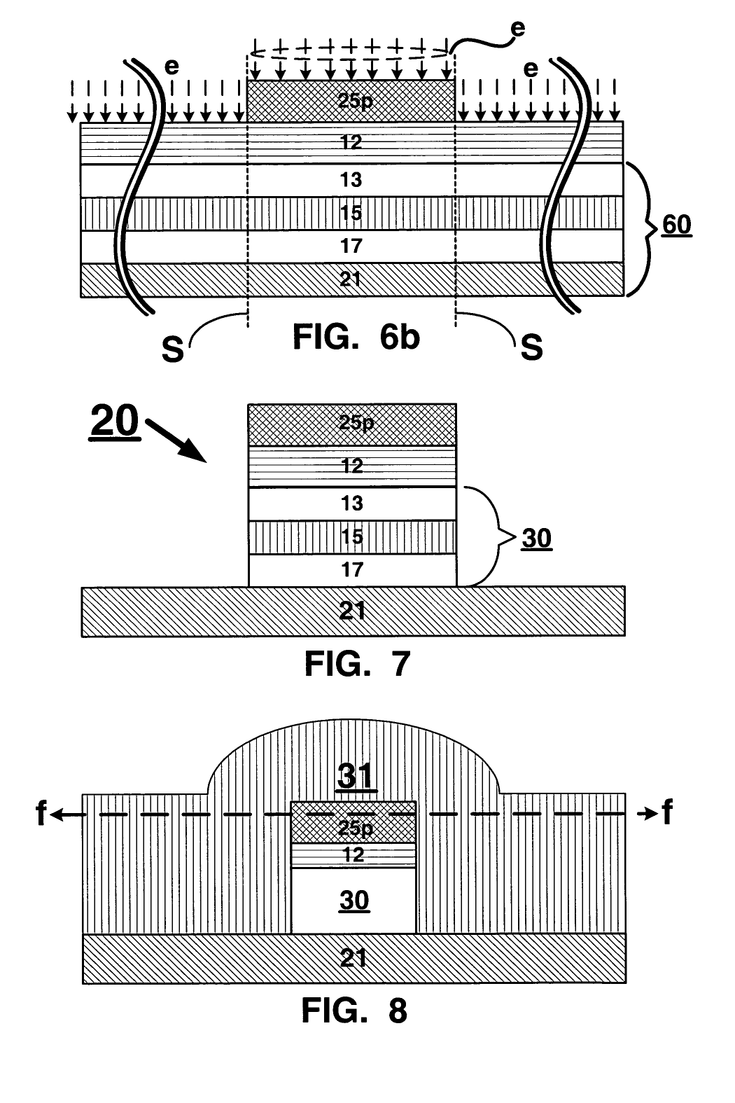

In FIG. 6a, at a stage 72, a first mask layer 25 is formed on the etch stop layer 12. The first mask layer 25 can be a material including but not limited to a photoresist material. At a stage 73, the first mask layer 25 is patterned. A photolithographic processes can be used to expose the first mask layer 25 with light L through a mask (not shown) so that the exposed portion is resistant to a material used to develop the photoresist.

In FIGS. 6b and 7, at a stage 74, the magnetic tunnel junction stack 60 is etched to remove excess portions (see dashed lines S) of the magnetic tunnel junction stack 60 to form a discrete magnetic tunnel junction stack 20. Exposed portions of the magnetic tunnel junction stack 60 are removed by an etch material that selectively removes the layers of the magnetic tunnel junction stack 60 that are not covered by a remaining portion (denoted as 25p) of the first mask layer 25 (i.e. on either side of the dashed lines S) to form the discrete magnetic tunnel junction stack 20. As described above, those portions of the magnetic tunnel junction stack 20 that include one or more layers of a magnetic material that will be protected against erosion by the etch stop layer 12 are collectively denoted as the layers 30.

In FIG. 8, at a stage 75, a dielectric layer 31 is formed on the discrete magnetic tunnel junction stack 20 and completely covers the discrete magnetic tunnel junction stack 20. Suitable materials for the dielectric layer 31 include but are not limited to silicon oxide (SiO₂) and silicon nitride (Si₃N₄). At a stage 76, the dielectric layer 31 is planarized until the dielectric layer 31 and the first mask layer 25p form a substantially planar surface (i.e. planarized along a dashed line f-f).

In FIG. 9, after the planarization, an upper surface 31s of the dielectric layer 31 and an upper surface 25s of the first mask layer 25p are substantially planar and are substantially flush with each other. For example, a process such as chemical mechanical planarization (CMP) can be used to planarize the first mask layer 25p and the dielectric layer 31.

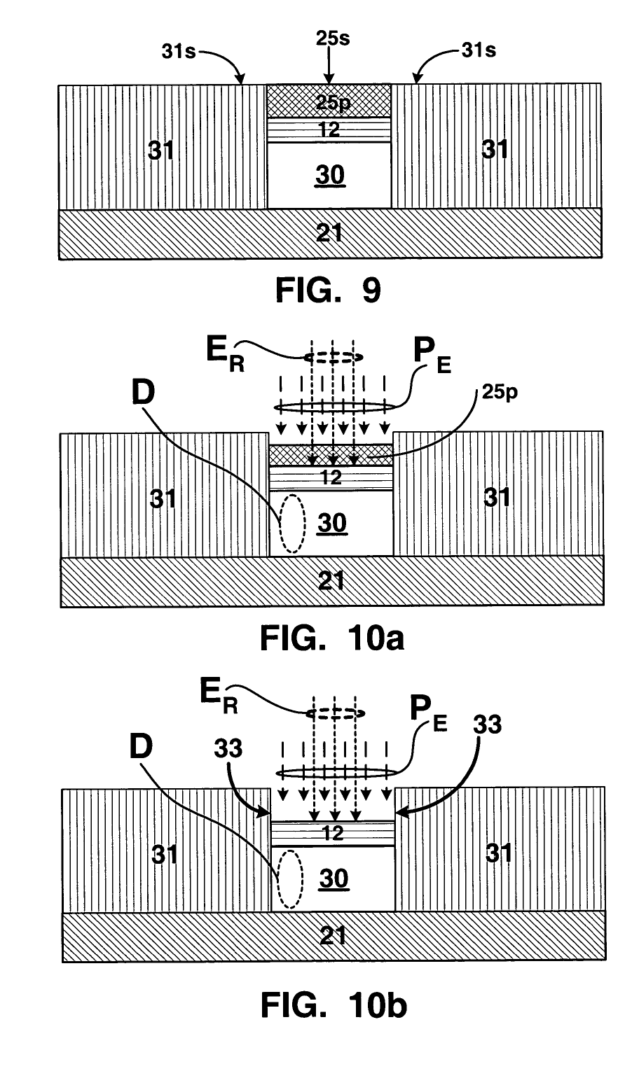

In FIG. 10a, at a stage 77, the first mask layer 25p is etched by an etch process P_{E} that selectively dissolves (i.e. removes) the first mask layer 25p. In FIG. 10b, the etching process P_{E} is continued until the first mask layer 25p is completely dissolved and a self-aligned via 33 is formed in the dielectric layer 31. The self-aligned via 33 extends all the way to the etch stop layer 12. The etch material used in the etch process P_{E} is not selective to the material of the etch stop layer 12 such that the etch stop layer 12 serves as a penetration barrier (see dashed arrows E_{R}) that protects the layers of magnetic material in the layers 30 that are positioned below the etch stop layer 12 from damage D that can be caused by chemical erosion.

The etch process P_{E} can be a plasma etch process or a wet etch process and an etchant material used in the etch process P_{E} can include the chemical fluorine (F). Fluorine (F) can chemically react with and erode the layers magnetic materials in the layers 30. For example, it is well understood in the MRAM art that a fluorine (F) based plasma etch can erode magnetic materials including but not limited to nickel (Ni), iron (Fe) and cobalt (Co). Because the data layer 13 and the reference layer 17 can include one or more of those materials and alloys of those materials, the etch stop layer 12 prevents chemical erosion of the nickel (Ni), the iron (Fe), and the cobalt (Co). The etch material can be a fluorine containing gas including but not limited to CF₄, CHF₃, C₄F₈, and SF₆. Additionally, for a plasma etch process, the etch material (i.e. the etch gas) can include oxygen (O₂) and fluorine (F) alone or in combination with other compounds as described above.

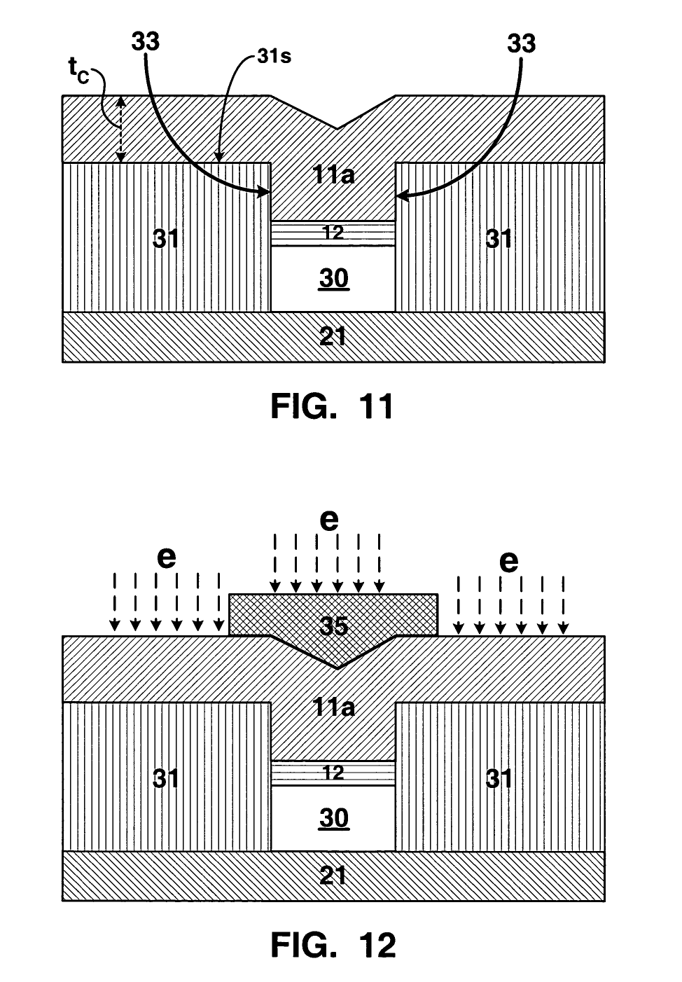

In FIG. 11, at a stage 78, a second electrically conductive material 11a is deposited on the dielectric layer 31. Preferably, the deposition continues until the second electrically conductive material 11a completely fills the self-aligned via 33 (i.e. the self-aligned via 33 is completely filled in) and the second electrically conductive material 11a extends outward of the upper surface 31s by a predetermined distance t_{c} (i.e. by a thickness t_{c}).

In FIG. 12, at a stage 79, the second electrically conductive material 11a is patterned. For instance, a photolithographic process and a photoresist material 35 can be used to pattern the second electrically conductive material 11a. After the pattern is developed, a portion of the photoresist material 35 remains and serves as an etch mask. At a stage 80, the second electrically conductive material 11a is etched to define a dual-damascene conductor 11. The dual-damascene conductor 11 is in contact with the etch stop layer 12. Suitable materials for the dual-damascene conductor 11 and the bottom conductor 21 include but are not limited to aluminum (Al), alloys of aluminum, tungsten (W), alloys of tungsten, copper (Cu), and alloys of copper.

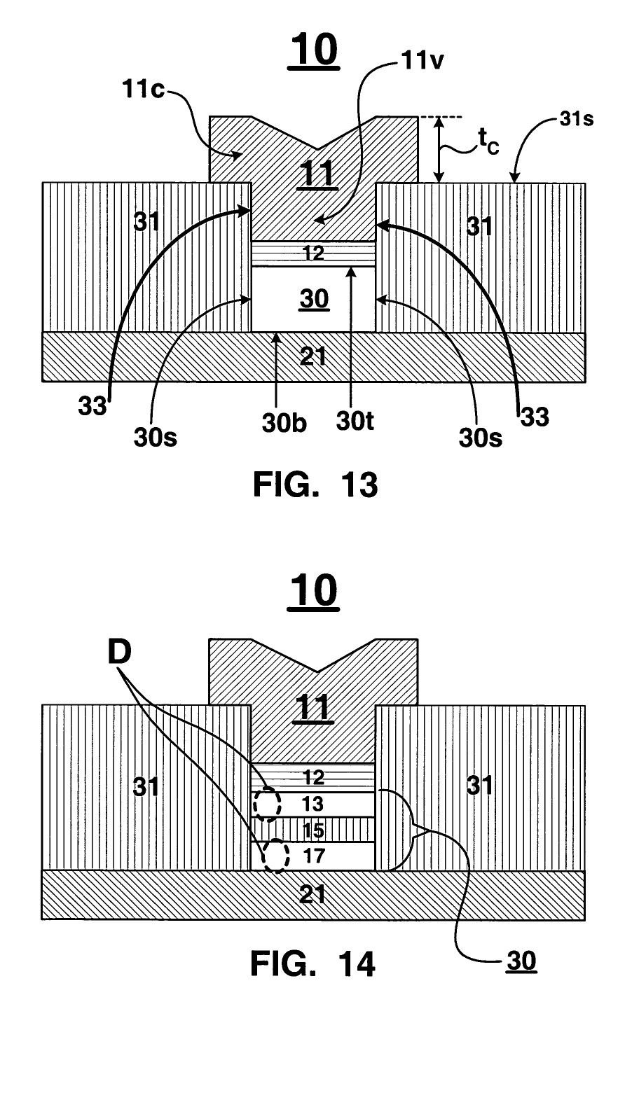

In FIG. 13, the dual-damascene conductor 11 includes a first portion 11v and a second portion 11c. The first portion 11v is a via that is positioned in the self-aligned via 33. The first portion 11v completely fills the self-aligned via 33 and is in contact with the etch stop layer 12. The second portion 11c is a top conductor that is in contact with the substantially planar surface 31s of the first dielectric material 31 and extends outward of the substantially planar surface 31s. The top conductor 11c can extend outward of the upper surface 31s by the predetermined distance tc. Collectively, the dual-damascene conductor 11 and the bottom conductor 21 can be referred to as write lines.

The method of the present invention allows the via 11v for the self-aligned via 33 and the top conductor 11c that will serve as one of the electrodes for the magnetic tunnel junction device 10 to be a homogeneously formed dual-damascene conductor 11 that are deposited in one step instead of two or more steps, thereby reducing the number of process steps.

As was described above, the order of the layers 30 in the discrete magnetic tunnel junction stack 20 need not be in the order depicted in FIGS. 7, 13 and 14. As an example, the data layer 13 can be in contact with the bottom conductor 21 and the reference layer 17 can be in contact with the etch stop layer 12, with the tunnel barrier layer 15 positioned between the data and reference layers (13, 17). As another example, a cap layer (not shown) can be positioned at the top portion 30 and in contact with the etch stop layer 12 and a seed layer (not shown) can be positioned at the bottom portion 30b.

Accordingly, in FIG. 13, the bottom conductor 21 is in electrical communication with a bottom portion 30b of the layers 30 and the etch stop layer 12 is in contact with a top portion 30t of the layers 30. The data and reference layers (13, 17), the tunnel barrier layer 15, and any of the other layers that comprise the layers in 30 (e.g. cap layers, seed layers, etc.) will be positioned between the bottom conductor 21 and the etch stop layer 12 in whatever logical order is dictated by the magnetic tunnel junction topology.

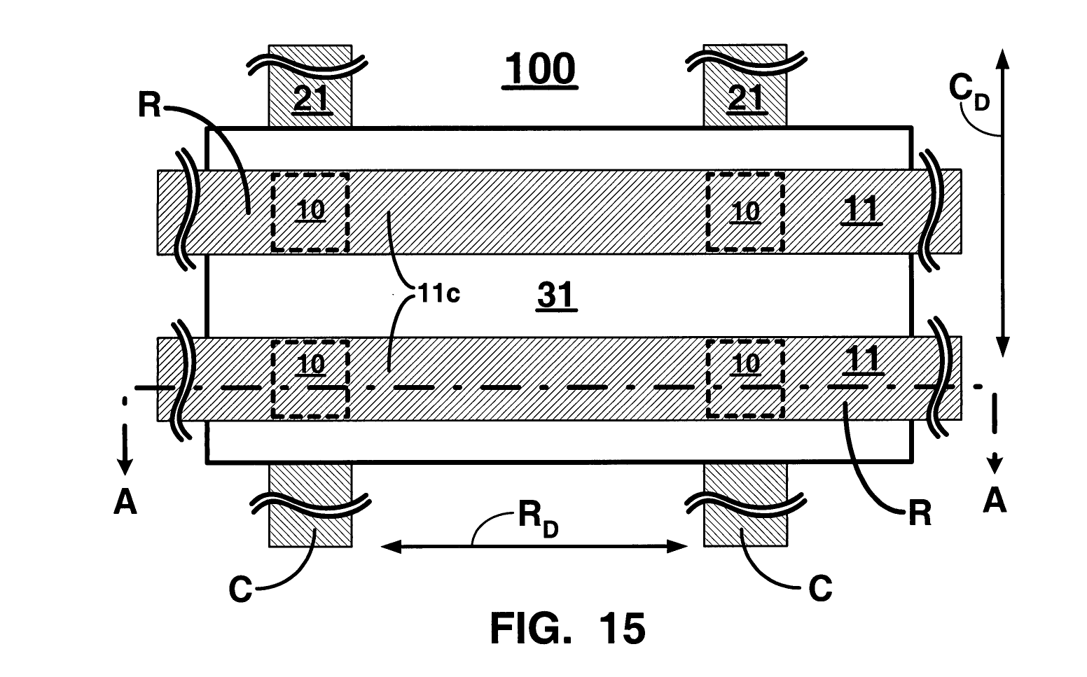

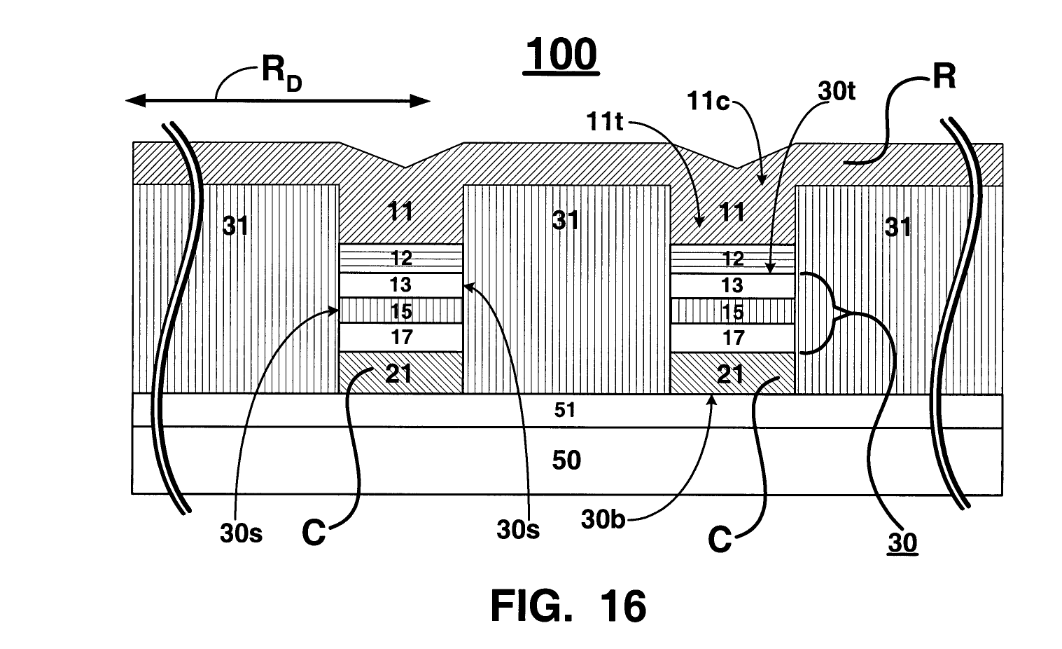

In FIGS. 15 and 16, the dual-damascene conductor 11 can be a row conductor R and the bottom conductor 21 can be a column conductor C, or vice-versa, in an array 100 that includes a plurality of the magnetic tunnel junction devices 10. The array 100 can be a MRAM used to store and retrieve data written to the plurality of magnetic tunnel junction devices 10. The dual-damascene conductor 11 is in contact with the etch stop layers 12 of the magnetic tunnel junction devices 10 in each of the rows R. The dual-damascene conductor 11 is aligned with a row direction R_{D} (see FIGS. 15 and 16) of the array 100. Similarly, the column conductor C is in electrical communication with one of the thin film layers 30 (e.g. the reference layer 17) of the magnetic tunnel junction devices 10 in each columns C and the column conductor C is aligned along a column direction C_{D} (see FIG. 15) of the array 100.

Each of the magnetic tunnel junction devices 10 is positioned between an intersection of the row and column conductors (R, C) as depicted by the dashed lines 10. Typically, the row and column conductors (R, C) cross the magnetic tunnel junction devices 10 at substantially right angles to each other. Accordingly, the row and column conductors (R, C) define the rows and columns of the array 100 and the magnetic tunnel junction devices 10 are positioned in the rows R and columns C of the array 100. The alterable orientation of magnetization M₂ in the data layer 13 is rotated (i.e. flipped) by passing currents (not shown) of sufficient magnitude through a selected row and column conductor (R, C) so that magnetic fields generated by those currents cooperatively combine to flip the alterable orientation of magnetization M₂.

Although several embodiments of the present invention have been disclosed and illustrated, the invention is not limited to the specific forms or arrangements of parts so described and illustrated. The invention is only limited by the claims.

1. A method of making a magnetic tunnel junction device, comprising:
forming a magnetic tunnel junction stack;
forming an etch stop layer on the magnetic tunnel junction stack, the etch stop layer comprising a first electrically conductive material;
forming a first mask layer on the etch stop layer;
patterning the first mask layer;
forming a discrete magnetic tunnel junction stack by etching the magnetic tunnel junction stack;
forming a dielectric layer that completely covers the discrete magnetic tunnel junction stack;
planarizing the dielectric layer until the dielectric layer and the first mask layer form a substantially planar surface;
forming a self-aligned via by etching away the first mask layer;
depositing a second electrically conductive material on the dielectric layer and in the self-aligned via;
patterning the second electrically conductive material; and
forming a dual-damascene conductor by etching the second electrically conductive material.

2. The method as set forth in claim 1, wherein the etching away the first mask layer comprises a plasma etch using an etch material comprising a gas containing fluorine.

3. The method as set forth in claim 2, wherein the etch material further includes oxygen.

4. The method as set forth in claim 1, wherein the etching of the first mask layer to form the self-aligned via comprises a wet etch using an etchant material including fluorine.

5. The method as set forth in claim 1, wherein the depositing of the second electrically conductive material is continued until the second electrically conductive material completely fills in the self-aligned via and extends outward of the substantially planar surface by a predetermined distance.

6. The method as set forth in claim 1, wherein the etching the first mask layer is continued until the first mask layer is completely dissolved and the self-aligned via extends to the etch stop layer.

7. A magnetic tunnel junction device, comprising:
a discrete magnetic tunnel junction stack including a top portion, a bottom portion, and a side portion;
an etch stop layer of a first electrically conductive material, the etch stop layer is in contact with the top portion;
a bottom conductor in electrical communication with the bottom portion; and
a dual-damascene conductor including a top conductor and a via, the via is in contact with the etch stop layer, and the top conductor and the via are homogeneously formed with each other.

8. The magnetic tunnel junction device as set forth in claim 7, wherein the first electrically conductive material for the etch stop layer is a material selected from the group consisting of aluminum and alloys of aluminum.

9. The magnetic tunnel junction device as set forth in claim 7, wherein the dual-damascene conductor is made from a material selected from the group consisting of aluminum, alloys of aluminum, tungsten, alloys of tungsten, copper, and alloys of copper.

10. The magnetic tunnel junction device as set forth in claim 7 and further comprising:
a plurality of the magnetic tunnel devices positioned in a plurality of rows and a plurality of columns of an array;
a plurality of row conductors that are aligned with a row direction of the array; and
a plurality of column conductors that are aligned with a column direction of the array,
each of the plurality of the magnetic tunnel junction devices is positioned between an intersection of one of the row conductors with one of the column conductors,
wherein the plurality of row conductors comprises a selected one of the dual-damascene conductor or the bottom conductor, and
wherein the plurality of column conductors comprises a selected one of the dual-damascene conductor or the bottom conductor.

11. The magnetic tunnel junction device as set forth in claim 10, wherein the array is a MRAM array.

12. A magnetic tunnel junction device, comprising:
a discrete magnetic tunnel junction stack including a plurality of thin film layers that include a data layer, a reference layer, and a tunnel barrier layer positioned between the data layer and the reference layer;
the plurality of thin film layers including a top portion, a bottom portion, and a side portion;
an etch stop layer of a first electrically conductive material, the etch stop layer is in contact with the top portion;
a bottom conductor in electrical communication with the bottom portion; and
a dual-damascene conductor including a top conductor and a via, the via is in contact with the etch stop layer, and the top conductor and the via are homogeneously formed with each other.

13. The magnetic tunnel junction device as set forth in claim 12, wherein the first electrically conductive material for the etch stop layer is a material selected from the group consisting of aluminum and alloys of aluminum.

14. The magnetic tunnel junction device as set forth in claim 12, wherein the dual-damascene conductor is made from a material selected from the group consisting of aluminum, alloys of aluminum, tungsten, alloys of tungsten, copper, and alloys of copper.

15. The magnetic tunnel junction device as set forth in claim 12, wherein the data layer is positioned at the top portion and the data layer is in contact with the etch stop layer.

16. The magnetic tunnel junction device as set forth in claim 12, wherein the reference layer is positioned at the top portion and the reference layer is in contact with the etch stop layer.

17. The magnetic tunnel junction device as set forth in claim 12, wherein the tunnel barrier layer is made from a dielectric material.

18. The magnetic tunnel junction device as set forth in claim 12 and further comprising:
a plurality of the magnetic tunnel devices positioned in a plurality of rows and a plurality of columns of an array;
a plurality of row conductors that are aligned with a row direction of the array; and
a plurality of column conductors that are aligned with a column direction of the array,
each of the plurality of the magnetic tunnel junction devices is positioned between an intersection of one of the row conductors with one of the column conductors,
wherein the plurality of row conductors comprises a selected one of the dual-damascene conductor or the bottom conductor, and
wherein the plurality of column conductors comprises a selected one of the dual-damascene conductor or the bottom conductor.

19. The magnetic tunnel junction device as set forth in claim 18, wherein the array is a MRAM array.

20. The magnetic tunnel junction device as set forth in claim 18, wherein the tunnel barrier layer is made from a dielectric material.
